(19) United States
(12) Patent Application Publication
(10) Pub. No.: US 2021/0327859 A1
(43) Pub. Date: Oct. 21, 2021

(54) PBC-LESS LIGHT EMITTING UNIT AND METHOD FOR MANUFACTURING THEREOF

(71) Applicant: VALOYA OY, Helsinki (FI)

(72) Inventor: Lars AIKALA, Lapinkyla (FI)

(21) Appl. No.: 16/851,817

(22) Filed: Apr. 17, 2020

(51) Int. Cl. H01L 25/13; H01L 33/48; H01L 33/58; H01L 33/54; H01L 33/64

(52) U.S. Cl. CPC H01L 25/13; H01L 33/486; H01L 33/58; A01G 7/045; H01L 33/64; H01L 2933/0058; H01L 2933/005; H01L 33/54

(57) ABSTRACT

The present disclosure relates to a method for manufacturing a PCB-less structure for a light emitting unit. The method includes a step of forming a light guide element for the light emitting unit. Electrical components (such as LED components) are embedded to the light guide element and electrical conductors are formed on the surface of the light guide element. An insulating layer in the form of a dielectric layer is then added on top of the components and the electrical conductors. As a result, the light guide element and the dielectric layer form a protective casing around the components and the electrical conductors. The light guide element also serves as a frame for the light emitting unit.

### BACKGROUND OF THE INVENTION

### Field of the Invention

The invention relates to manufacturing of light sources, and, in particular, to cost-efficient methods of manufacturing LED light sources.

### Description of the Related Art

Greenhouses and growth rooms utilize artificial lighting in supplementing, supporting or replacing natural light provided by the sun. As a result, greenhouses and growth rooms enable growing plants outside their natural growth season and growing plants of foreign climatic conditions.

Light emitting diodes (LEDs) have proved to be an energy-efficient approach for implementing lighting in a greenhouse or a growth room. A light emitting unit may be formed by mounting a plurality of LEDs on a printed circuit board, for example. A printed circuit board (PCB) mechanically supports and electrically connects electrical or electronic components using conductive tracks, pads and other features etched from one or more sheet layers of copper laminated onto and/or between sheet layers of a non-conductive substrate. Components are generally soldered onto the PCB to both electrically connect and mechanically fasten them to it. PCB manufacturing processes have a long history, and there are many standardized materials for the processes. FR-4 and MCPCB are examples of commonly used laminate materials. The PCB manufacturing processes can produce PCBs with good electrical characteristics, such as good conductivity and switching characteristics.

However, for light sources may also have other requirements that may have to be considered. For example, a light source intended to be used in a cultivation space may require a high ingress protection. A cultivation environment typically has a combination of high humidity and high ambient temperature. In conventional LED light sources, ingress protection may be improved by sealing the whole PCB in a protective casing. However, this may require complicate mechanical implementation. Manufacturing such an implementation cost-efficiently may be very challenging.

### SUMMARY OF THE INVENTION

An object of the present disclosure is to provide means for alleviating the above disadvantages. This object is achieved by a method and products which are characterized by what is stated in the independent claims. The preferred embodiments of the disclosure are disclosed in the dependent claims.

The present disclosure relates to a method for manufacturing a PCB-less structure for a light emitting unit. The method comprises a step of forming a light guide element for the light emitting unit. Electrical components (such as LED components) are embedded to the light guide element and electrical conductors are formed on the surface of the light guide element. An insulating layer in the form of a dielectric layer is then added on top of the components and the electrical conductors. As a result, the light guide element and the dielectric layer form a protective casing around the components and the electrical conductors. The light guide element also serves as a frame for the light emitting unit. In this manner, a simple and robust structure for the light emitting unit can be achieved.

Another advantage of a light emitting unit according to the present disclosure is improved maintainability of the luminaires using the light emitting unit. In conventional light sources, sufficient ingress protection may be achieved by sealing the whole light source. In contrast, the light emitting unit according to the present disclosure forms a sealed unit by itself. Therefore, the rest of the light source may have lesser requirements with respect to ingress protection. Further, since the light emitting unit can be formed as an integral module, it is easier to replace when needed.

### BRIEF DESCRIPTION OF THE DRAWINGS

In the following the invention will be described in greater detail by means of preferred embodiments with reference to the attached drawings, in which

FIG. 1 shows a simplified, exemplary flow diagram of a manufacturing method according to the present disclosure;

FIG. 2 shows a simplified example of a light emitting unit according to the present disclosure;

FIGS. 3a and 3b show a simplified examples of a carrier according to the present disclosure;

FIG. 4 shows an example of adhesive applied at locations to which components are mounted;

FIGS. 5a and 5b show a simplified example of a surface-mount LED component;

FIG. 6 shows an example of components mounted on a carrier;

FIGS. 7a and 7b show simplified examples of a light guide elements according to the present disclosure.

FIG. 8 shows an example of the carrier being removed;

FIG. 9 shows an embodiment of electrical circuitry formed on the first surface of a light guide element;

FIG. 10 shows and example of dielectric layer formed on top of a first surface of a light guide element;

FIGS. 11a and 11b show cross-sectional examples of forming a connector assembly; and

FIG. 12 shows a cross-sectional view of one embodiment of a light emitting unit according to the present disclosure.

### DESCRIPTION OF THE PREFERRED EMBODIMENTS

The present disclosure describes a method for manufacturing a light emitting unit and prefabrication elements for the light emitting unit. The present disclosure also describes said light emitting unit and prefabrication elements for such a light emitting unit. In the context of the present application, the term “light emitting unit” refers to an element, a unit, a device or a module that can be used as a source of light emission in a light source, such a lighting fixture. In addition to the light emitting unit, a light source may also comprise other parts, such as control electronics, cabling, connectors, fastening devices, etc. In some embodiments, however, the light emitting unit may be used as a lighting fixture as such.

A light emitting unit according to the present disclosure can be formed without a PCB. In other words, no PCB (i.e. a laminate made of substrate and conductor layers) is needed in the manufacturing method or the light emitting unit. Thus, the light emitting unit can be considered PCB-less.

A light emitting unit according to the present disclosure can be formed to be suitable for plant cultivation. In practice, this may mean that the unit has sufficient ingress protection and sufficient means for operating temperature management. For growth room cultivation, a sufficient ingress protection code (IPC) may be at least IP65. Preferably, the IPC is at least IP67. These levels of ingress protection can be achieved with the light emitting unit according to the present disclosure. The present disclosure discusses lighting in relation large-scale horticultural applications. Lighting fixtures and lighting arrangements utilising the light emitting units according to the present disclosure may be intended for professional use, e.g. or research or commercial production of plants. Thus, power rating of a light emitting unit according to the present disclosure may range from tens of watts (10 W or more) to hundreds of watts (100 W or more), for example. In order to manage waste heat caused by the generation of light emission, the light emitting unit may be formed such that it can easily be provided with or attached to a heat sink, for example.

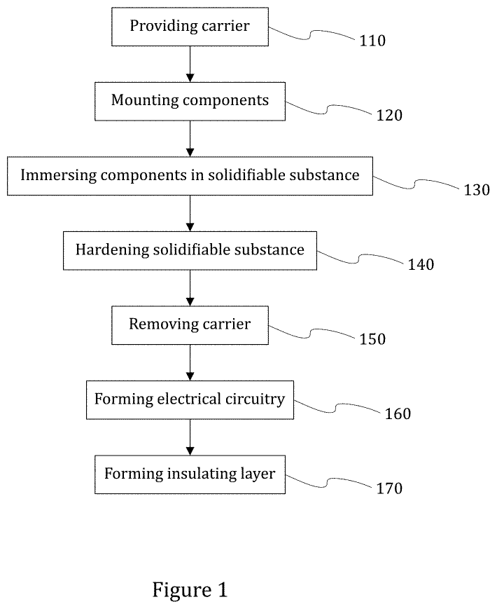

An overview of a method for manufacturing a light emitting source according to the present disclosure is presented below. FIG. 1 shows a simplified, exemplary flow diagram of a manufacturing method according to the present disclosure. In the manufacturing method according to the present disclosure, a carrier with an adhesive on its first side is provided and components are placed on the first side of the carrier. In FIG. 1, the carrier is provided in step 110 and the components are mounted in step 120. The components are placed their bottom side facing the first side of the carrier so that contact terminals of the components engage with the adhesive on the first side.

The placed components are then immersed in a viscous hardenable substance in a mould. This is shown in FIG. 1 as step 130. The mould defines structural features for a light guide element. Next, the hardenable substance is hardened to form the light guide element. In FIG. 1, the hardening is done in step 140. As a result of the hardening, the light guide element forms a frame for the light emitting unit. The light guide element has a first surface in contact with the first side of the carrier. Preferably bodies of the components are mostly or completely embedded within the light guide element.

The carrier may then be removed, thereby exposing the contact terminals of the components on the first surface of the light guide element. The removal of the carrier is shown as step 150 in Figure. Electrical circuitry may then be formed on the exposed first surface of the light guide element. In FIG. 1, this is performed in step 160. Once the electrical circuitry has been formed on the first surface of the light guide element, a dielectric layer may be formed on top of the first surface, thereby covering the electrical circuitry and components. Step 170 in FIG. 1 relates to the forming of the dielectric layer.

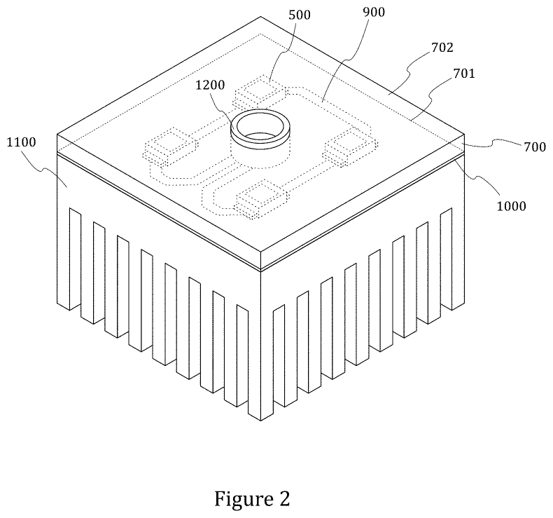

As a result of the above-discussed method steps, a light emitting unit according to the present disclosure may be produced. FIG. 2 shows a simplified example of such a light emitting unit. As shown in FIG. 2, a light emitting unit according to the present disclosure may comprise a light guide element 700 with a substantially planar first surface, a plurality of surface-mount LED components 500 embedded within the light guide element 700, electrical conductors 900 formed on the first surface 701 of the light guide element 700, and an dielectric layer 1000 formed on top of the first surface 701 of the light guide element 700, covering the electrical circuitry and LED components 500.

In FIG. 2, four LED components 500 are embedded within a light guide element 700. However, a light emitting unit according to the present disclosure may comprise any plurality of LED components. Higher cost-effectiveness may be achieved if a large number of LED components are integrated to a light emitting unit. Therefore, the number of LED components may be counted in tens (ten or more), or even in hundreds (100 or more), of LED components, for example. In order to be able to accommodate the large number of LED components, the light guide element may be large in size. For example, in some embodiments, the width of the light guide element may be several centimetres (e.g. at least 3 cm). However, the manufacturing methods according to the present disclosure enable manufacturing of even larger light emitting units. For example, the width may also be at least 5 cm or even at least 10 cm. The length of the light guide element is preferably larger than the width. With an elongated shape, the light emitting unit may be easier to use in conventionally shaped lighting fixtures. The width may be 10 cm or more, for example. Depending on the application, the length may be at least 20 cm, or even at least 50 cm

In a light emitting unit according to the present disclosure, bodies of the LED components are mostly or completely embedded within the light guide element while contact terminals of the LED components reach to or extend from the first surface of the light guide element. The electrical conductors are galvanically connected to at least some of the contact terminals of the LED components. An dielectric layer covers the electrical circuitry and LED components. In FIG. 2, the bodies of LED components 500 are completely embedded within the light guide element 700. However, their contact terminals reach to the first surface 701 where they form connections to the conductors 900. FIG. 2 also shows a connector assembly 1200 that extends through the light guide element 700 from the first surface 701 to the second surface 702.

In some embodiments of a light emitting unit according to the present disclosure, additional cooling may be required. Therefore, the light emitting unit may further comprise a heatsink attached to the first surface 702 on top of the dielectric layer 1000. FIG. 2 shows a heat sink 1100 attached to the dielectric layer 1000 and a connector assembly 1200 that extends through the light guide element 700 from the first surface 701 to the second surface 702.

Various aspects of the method according to the present disclosure and products manufactured with the method are now discussed in more detail. Unless explicitly otherwise indicated, each aspect discussed below can be combined with the rest of the aspects discussed below. Further, the method and products according to the present disclosure is not limited to the examples described below.

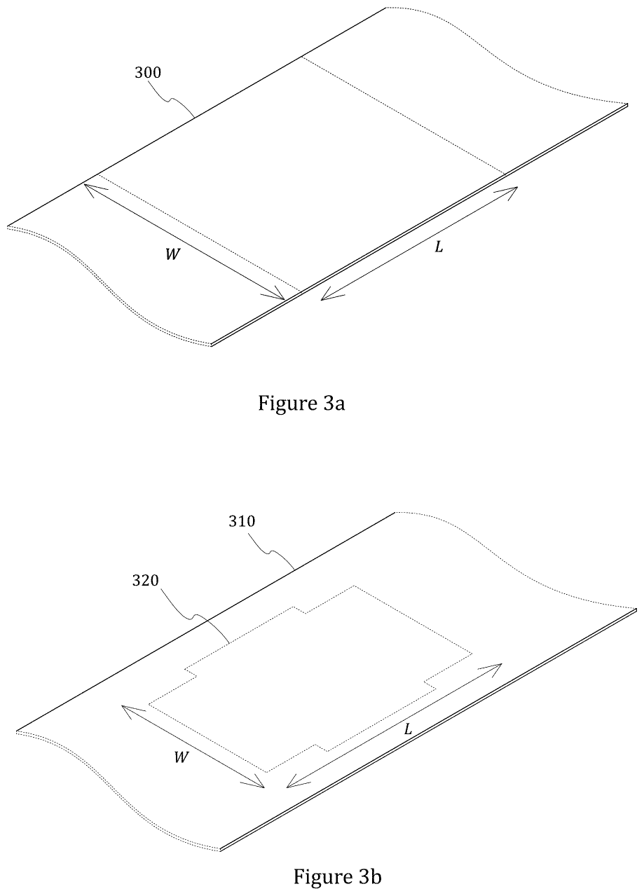

First, various aspects of carriers according to the present disclosure are discussed in more detail. As mentioned above, a method according to the present disclosure comprises providing a carrier with adhesive on its first side. In the context of the present application, a carrier is an element on which components can be mounted. The carrier has at least first side that is essentially flat. The carrier may be in the form of a film, sheet, board or plate, for example. In the context of the present disclosure, the surface of the first side can be considered to define a geometrical plane for the carrier. Dimensions “length” and “width” of the carrier are two orthogonal dimensions that run along this plane. Dimension “thickness” is perpendicular to said plane. FIGS. 3a and 3b show simplified examples of a carrier. In FIG. 3a, the carrier 300 is in form of a rectangular piece of a continuous sheet or a ribbon. The carrier 300 has a length L and a width W. The shape of the carrier may depend on the application. The carrier may be cut into shape by stamping or with laser cutting, for example. FIG. 3b shows an exemplary embodiment where a carrier has been formed to a sheet-like material 310 by cutting the material to a shape 320. The cutting into shape may occur before or after the placing of the components. The shape 312 has a length L and a width Win FIG. 3b.

In some embodiments, the carrier may be made of a flexible material or materials. This enables the carrier being provided as a continuous sheet/strip/tape from a roll, for example. If the carrier can be provided as a continuous sheet/strip/tape for a machinery performing the step of mounting the components, said step may be simplified and/or accelerated. Therefore, in some embodiments of the method, the cutting of the carrier into shape may occur after the mounting of the components. On the other hand, in some embodiments, surface mount equipment (SME) performing the mounting of components may not be able to handle a continuous sheet/strip/tape. Thus, it may be advantageous to cut the carrier into shape already before mounting the components.

The material or materials of the carrier are preferable non-elastic so as to minimize the risk of misalignment and/or unintentional detachment of components mounted on the carrier. In other words, the material does preferably not shear or stretch much, at least along the plane of the carrier, i.e. along dimensions length and width. As an alternative to a flexible structure, the carrier can also be a rigid structure, such as an aluminium plate. In such a case, the plate may be used together with the mould to form a sealed cavity (for injection moulding, for example).

The carrier may be disposable or it may be reusable. For example, it the carrier is made of a low-cost material, it may not be durable enough to be reused. However, reusing the carrier may be the more cost-efficient choice when it is in the form of an aluminium plate. In some embodiments of the method according to the present disclosure, the carrier may be made of a transparent material. The facilitates giving an UV light treatment to the hardenable substance when the components are immersed in it in the mould.

In one embodiment, the first side of the carrier may be a flat, smooth surface. When the first side is flat and smooth, adhesive can be easily applied to it. In another embodiment, the first side may be mostly flat but may also comprise small surface structures, such as ridges or channels.

Second, various aspects of adhesives according to the present disclosure are discussed in detail. In the context of the present disclosure, the adhesive on the first side of the carrier should be such that it is sufficiently strong for adhering to the components while at the same time being releasable. In this context, the term “releasable” means that the carrier can be reliably separated from the light guide element without damaging either of them. In some embodiments of the method according to the present disclosure, the adhesive may be such that the carrier can be removed from the light guide element solely by mechanical means. For example, the adhesive may be such that the carrier can be just peeled off the light guide element. Alternatively, the adhesive may be such that the carrier may be separated from the light guide element by applying a treatment to the adhesive. This treatment may be a heat treatment, a light treatment or a chemical treatment, for example.

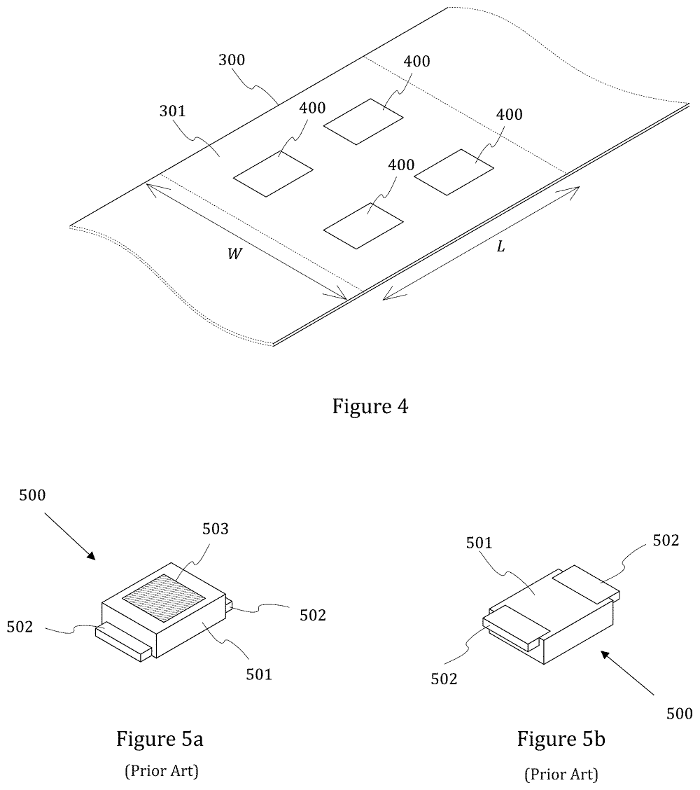

In some embodiments of the methods according to the present disclosure, the adhesive may completely cover the first side. Manufacturing of a carrier with such a first side may be simpler. Alternatively, the first side may be only partially covered by adhesive. For example, adhesive may be applied on the first side only on the locations to which the components are mounted. In this manner, less adhesive is need and handling of the carrier may be easier. FIG. 4 shows an example of adhesive applied at locations to which components are mounted. In FIG. 4, patches 400 of adhesive have been applied to a first side 301 of the carrier 300. The carrier 300 may be the same as in FIG. 3a, for example.

Third, various aspects of components according to the present disclosure are discussed in detail. The components are preferably surface-mount components. A surface-mount component typically has a block-shaped body and a plurality of contact terminals extending from the body. A semiconductor chip, such as a LED semiconductor chip is encased withing the body, and the contact terminals provide connections to the semiconductor chip. FIGS. 5a and 5b show a simplified example of a surface-mount LED component. In FIG. 5a, the LED component 500 is shown from its top side. The LED component 500 has a body 501 and two contact terminals 502. FIG. 5b shows the same component 500 from its bottom side. In the context of the present disclosure, the term “contact terminals” refers to a terminal intended for forming an electrical and/or thermal connection. For example, a LED component may have two contact terminals for electrical connection (anode and cathode) and optionally one terminal for thermal connection (thermal relief). A surface-mount component typically has contact terminals only on one the bottom side of the component. In conventional PCB-based electronics, the components are mounted on the PCB such that the bottom side faces the surface of the PCB so that the contact terminals engage with solder pads of the PCB. In FIG. 5b, the contact terminals are shown to be positioned on the bottom side. The opposing side to the bottom side, i.e. the top side, typically has only markings identifying the component. In case of a surface-mount LED component, the light emitting portion of the LED component is typically on the top side. FIG. 5a shows a light emitting portion 503 on the top side of the component 500.

Large components may be more prone for completely or partially detaching from the adhesive. In particular, if the carrier is flexible, special care may have to be taken so that large components are partially or completely detached from a carrier being bent. Preferably the length and width of the components are less than 10 mm. For example, the components may be SMD LEDs in 2835, 3030, 5670 or other LED packages. In order to ensure high ingress protection, the component should remain encased in the light guide element from its top side even if the thickness of the light guide element is small. Thus, the thickness of the components is preferably less than 7 mm.

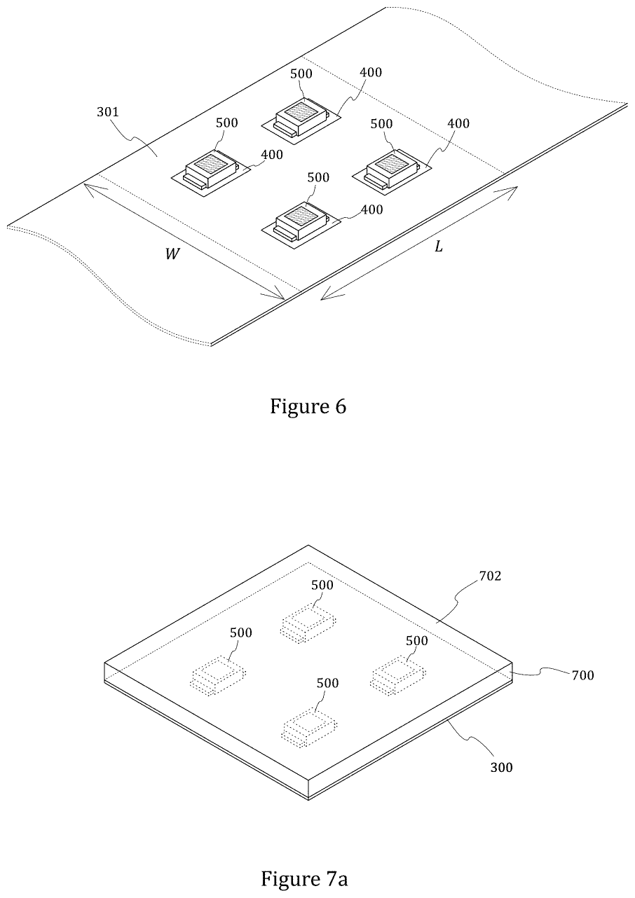

In the method according to the present disclosure, the components (such as surface-mount LED components) are placed on the first side of the carrier. The components may be mounted to predetermined locations on the first side. The first side has adhesive at least at said locations. The locations may form a pattern, and this pattern may reflect the locations of the components in the final product, such as a light emitting unit. The components are placed their bottom side facing the first side of the carrier so that at least the contact terminals of the components engage with the adhesive on the first side. FIG. 6 shows an example of components mounted on a carrier. In FIG. 6, components 500 are mounted on the first side 301 of the carrier 300. The components 500 are placed on the first side 301 such that their bottom side face the first side 301.

In methods according to the present disclosure, the components may be pressed against the first side until the adhesive forms a sufficient bond between the component (and/or its contact terminals) and the first side. In the context of the present disclosure, the term “sufficient bond” refers to a bond provided by the adhesive, where the is strong enough to keep the components from detaching (partially or completely) from the carrier before the light guide has been hardened in the method according to the present disclosure. With some adhesives, a sufficient bond may be formed instantaneously.

In some embodiments, the mounting of the components may be automatically performed. For example, the components may be mounted on the carrier with surface mount equipment (SME), such as a pick-and-place (P&P) machine, used in conventional PCB manufacturing processes. This may be particularly feasible when the components are standard-size surface-mount components.

In some embodiments, the carrier may be flexible in the direction of its thickness so that it yields when a component is being pressed against it. In this manner, the component can be pressed against the surface of the first side with a force securing the sufficient bond between the component and the first side but without damaging the component. In embodiments where the carrier and/or its first side is rigid, the adhesive may be in the form of an adhesive paste applied to the first side, for example. The components may be pressed against and/or partially into the adhesive paste so as to form a sufficient connection between the component and the adhesive paste.

While the present disclosure mostly refers the components being LED components, other components may also be mounted on the carrier. For example, passive components, such as surface-mount resistors and capacitors may be mounted on the carrier. In some embodiments, the light emitting unit may also comprise control electronics used for controlling the LED components. At least a part of the control electronics may be mounted on the carrier along with the LED components. In some embodiments, a plurality of same patterns of components may be mounted on the same carrier. For example, components of a batch of light emitting units may be mounted on the same carrier. This may be preferable for instance when the carrier supplied from a carrier roll, for example.

Fourth, various aspects of light guide element according to the present disclosure are discussed in detail. As described earlier, the method according to the present disclosure comprises immersing the placed components in a viscous hardenable substance in a mould in order to form a light guide element. The immersion of the components may be implemented in various ways. The components may be immersed in a hardenable substance already in the mould or the hardenable substance may be added after positioning the components in the mould. For example, the hardenable substance may be in the form of a liquid provided in an open mould. The components mounted on the first side of the carrier may be dipped into the liquid. In another example, the carrier and the mould may form a closed cavity into which the hardenable substance is injected. Once the mould is filled with the hardenable substance, the components may completely or mostly embedded within the substance.

In the context of the present application, the term “hardenable substance” refers to a substance that can be hardened into solid form. The hardening may be achieved via a treatment, for example. This treatment may be in the form of applying heat or UV light to the substance, for example. If the carrier is made of a transparent material, applying an UV light treatment is easier. The hardening may also be achieved via a chemical process, e.g. via curing. For example, the hardenable substance may be a composition of two or more composite substance which, when mixed together, start to react together and harden into a solid material. Thus, the phrase “hardenable substance” may refer to a substance or a composition of composite substances that can be hardened. Further, the term “viscous” is intended to understood as something that can be injected or cast to the mould. Synthetic resins, such as epoxy, acrylic, and silicone casting resins, are an example of viscous hardenable substances. Another example of hardenable substance is paraxylylene.

When the hardenable substance hardens, a light guide element is formed. In the context of the present application, the term “light guide element” refers to an element that acts as an optical path for light emitted by a light source, such as LED components. The hardenable substance may be selected such that it turns into a stiff material so that the light guide element may form a frame a light emitting unit according to the present disclosure.

In order to provide a good optical path, the hardenable substance is preferably highly transparent after being hardened. For example, 90% (or preferably even 95%) of incident light (emitted by the LED components) may pass through the light guide element uninterfered. However, in some embodiments, the light guide element may be provided with down-conversion material that converts at least some part of the incident light emission to lower energy light emission (i.e. higher wavelength light emission). Various phosphors exhibiting luminance are examples of down-conversion materials.

The light guide element is preferably in the form of an integral block within which the components are at least partially encased. The bodies of the components are preferably mostly embedded within the light guide element. Even more preferably, the bodies of the components are completely embedded within the light guide element. In this context, the phrase “mostly embedded” and “completely embedded” refers to most of the whole surface of the body being covered with the material of the light guide element. In other words, the bodies of the components are mostly or completely submerged beneath the first surface. By having the bodies of the components mostly or completely embedded within the light guide element, sufficient ingress protection can be more easily achieved. At the same time, however, it is preferable that the contact terminals of the LED components reach to or extend from the first surface of the light guide element first side of the light guide element. In other words, it is preferable that the contact terminals are not completely embedded below the first surface of the light guide element. In this manner, electrical connections can be formed to the contact terminals without having to remove material from the first surface.

The carrier and the mould together define structural features for the light guide element. The carrier, for its part, may alone define at least some structural features of the shape of the light guide. For example, the hardenable substance may be in touch with the first side of the carrier and, after hardening, the light guide element may have a first surface in contact with the first side of the carrier.

This first surface may be in the form of an essentially planar surface corresponding with the surface of first side of the carrier. The essentially planar surface may be flat or it may have small structures formed on it.

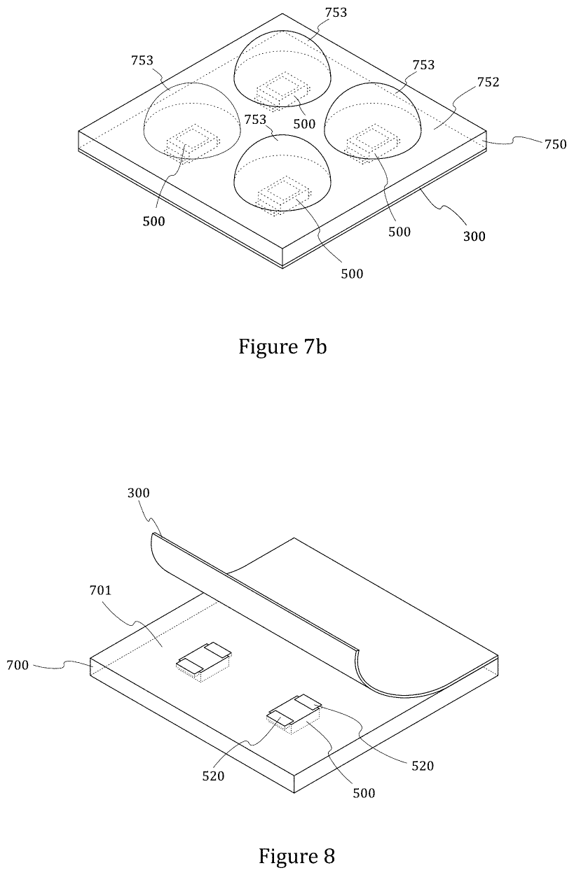

The mould may also define structural features for a light guide element. In other words, the shape of the light guide element is at least partially defined by the shape of the mould. For example, a second surface opposite to the first surface may be defined by the mould. In some embodiments, the second surface is flat, and the first and second surface define a plate-like structure with a constant thickness. FIG. 7a shows a simplified example of such an embodiment. In FIG. 7a, a light guide element 700 is show from its second side 702. Bodies of LED components 500 mounted on carrier 300 are encased in the light guide element 700 in FIG. 7a.

In other embodiments, the second surface is not flat but comprises surface structures, e.g. in the form of small domes. These domes may act as lenses LED components embedded within the light guide element, for example. FIG. 7b shows an example of a light guide element 750 where the second surface 752 of the light guide element 750 comprises dome-shaped structures 753 directly above the LED components 500.

The carrier and the mould may together define the thickness of the light guide element. The thickness of the light guide element is preferably large enough that the bodies of the components can be mostly or completely embedded within the light guide element. However, at the same time, it may be preferable to keep the thickness as small as possible in order to minimize the weight of the light guide element. Preferably an average thickness of the light guide element is less than 7 mm. Even more preferably, the thickness is less than 4 mm.

In some embodiments, a plurality of carriers engage with a single mould. In addition, or alternatively, a plurality of devices, such as light emitting units may be defined on a single carrier. As a result, a single block of transparent material with components of a plurality of devices is formed. This block may be used as for a light emitting unit with separately controllable regions, for example. Alternatively, the block may be divided into a plurality of pieces. The pieces be separated from each other by machining (sawing, cutting, drilling) or by laser cutting, for example. Thus, a plurality of devices can be produced from a single moulding.

The material of the light guide element, resulting in from the hardening of the hardenable substance, preferably has some specific characteristics. For example, the hardened material of the light guide element is preferably dielectric, i.e. it acts as a good electrical insulator. In this manner, operation of electrical circuitry formed by the components within the light guide element and the conductors on the first surface of the light guide element can be ensured. At the same time, thermal conductivity of the material is as high as possible so that it is able to conduct heat generated by the components away from them.

Fifth, aspects of formation of electrical conductors on the first surface of the light guide element are discussed in more detail. While the carrier is attached to the light guide element, it acts as a removable cover sheet covering the first surface. This cover covers the contact terminals of components embedded within the light guide element. The cover (i.e. the carrier) may be removed, thereby exposing the contact terminals of the components on the first surface of the light guide. FIG. 8 shows an example of the carrier being removed. The view direction is opposite to the view direction of FIGS. 7a and 7b. In FIG. 8, the carrier 300 has been partially peeled of the first surface 701 of a light guide element 700. The light guide element 700 may be the same or similar as in FIG. 7a, for example. As the carrier is being peeled off, the contact terminals 502 of the LED components 500 become exposed a galvanic connection on the first surface 701 of the light guide element 700.

The carrier can be removed in various ways. In case of a flexible carrier, it may be mechanically peeled of the first surface of the light guide element. In case of a disposable carrier, the carrier may be chemically dissolved. A rigid carrier may be detached from the light guide element by heating, for example.

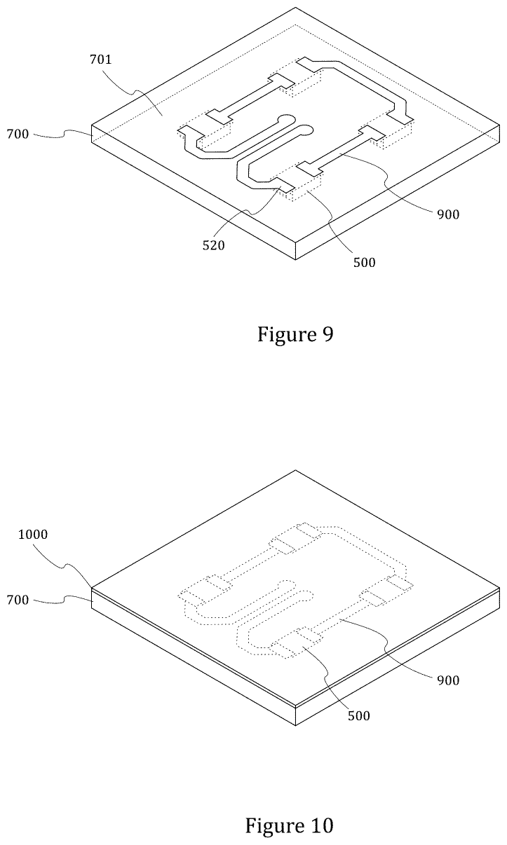

Once the cover (i.e. the carrier) has been removed from first surface of the light guide element, electrical circuitry may be formed on the first surface. The electrical circuitry may comprise electrical conductor traces, for example. At least some of the conductor traces may connected to the contact terminals of the components. FIG. 9 shows an embodiment of electrical circuitry formed on the first surface of a light guide element. In FIG. 9, conductors 900 connect contact terminals 502 of components 500 on the first surface 701 of the light guide element 700.

The electrical circuitry may be formed on the first surface by various different methods. For example, printed electronics may be used. In the context of the present disclosure, the term “printed electronics” refers a set of printing methods that may be used to create electrical devices and/or circuitry on various substrates. Printing may use common printing equipment suitable for defining patterns on material, such as screen printing, flexography, gravure, offset lithography, and inkjet. Electrical conductors in printed electronics have conventionally been considered to have poorer conductivity and longer switching times than a conventional PCB. However, the number of components and electrical conductors forming connections between the components may be relatively low compared with a typical PCB. For example, the electrical conductors of a LED-based light emitting unit may mostly be dedicated providing current for the LED components. The LED components may be two-terminal components (e.g. anode and cathode), and therefore, the number electrical conductors forming the connections between the components may be very low, especially if the LED components are connected in series. Therefore, the electrical conductors can be made physically wider (and if necessary, thicker) than in a conventional PCB in order to improve their conductivity.

While the present disclosure discusses the forming of the electrical circuitry mainly in relation to printed electronics, methods according to the present disclosure are not limited to only to them. For example, similar methods as used in conventional PCB manufacturing may also be used in methods according to the present disclosure.

Sixth, aspects of formation of a dielectric on the first surface of the light guide element are discussed in more detail. After the electrical circuitry has been formed on the first surface of the light guide element, a dielectric layer may be formed on top of the first surface, thereby covering the electrical circuitry and LED components. One aspect of the dielectric layer is that it provides electrical insulation for the components and the electrical conductors on the first surface. In addition, the dielectric layer preferably also improves the ingress protection of the components and the conductors. The dielectric layer preferably seals the components and the conductor within uniform cover, and together the dielectric layer and the light guide element form a protective casing for the components and the conductors. At the same time, however, the material preferably has high thermal conductance characteristics so that it can conduct heat away from the components (and the electrical conductors formed on the first surface). For example, the thermal conductance of the material may be in the range of 1 to 4 W/mk. Preferably, the thermal conductance is 2 to 4 W/mK. FIG. 10 shows and example of dielectric layer formed on top of a first surface of a light guide element. In FIG. 10, the components 500 and the conductors 900 are covered by a dielectric layer 1000. The dielectric layer may be formed by applying suitable material in the form of paint or a paste applied to the first surface, for example. Another example of forming the dielectric layer is using dielectric polymerized glass reinforced bond sheets, which provide both dielectric and high thermal conductivity.

Seventh, aspects of heat dissipation control are discussed in more detail. In some embodiments, the components embedded within the light guide element may produce so much heat that it cannot be simply dissipated to ambient air via the surface of the dielectric layer. Therefore, some embodiments of the manufacturing method according to the present disclosure may comprise attaching a heatsink to the first surface of the light guide element on top of the dielectric layer. The heat sink may be in the form of a metal block with a flat surface on one side and a plurality of cooling fins extending from the opposite side, for example. In order to provide as large thermal connection between the heat sink and the dielectric layer as possible, the outer surface of the dielectric layer is preferably flat. A flat outer surface for the dielectric layer can be achieved by making the dielectric layer at least as thick as electrical conductors on the first surface of the light guide element and/or by embedding the electrical conductors in the light guide element.

Eighth, aspects of using placeholder elements in the formation of the light guide element are discussed in more detail. In some embodiments, other elements may be mounted on the first side of the carrier in addition to the components. For example, methods according to the present disclosure may comprise placing a placeholder element on the first side of the carrier. After hardening the hardenable substance, the placeholder element may then be removed to form a shaped cavity in the light guide, and a circuit element may be mounted in the cavity. In this context, the term “shaped cavity” refers to a cavity with a predetermined shape. This predetermined shape preferably corresponds with the shape of the circuit element so that at least part of the element fits in the cavity. The circuit element may be a connector assembly, for example. The connector assembly may comprise an electrical connector (e.g. a socket for a plug), a cable clamp, and a sealing device for example. Once fitted in the cavity, the connector assembly may form a waterproof electrical connector interface, for example. Similar to the LED components, for example, the connector assembly may be embedded within the light guide element such that a base part of the connector assembly is mostly or completely embedded within the light guide element while contact terminals of the connector assembly reach to or extend from the first surface of the light guide element. The electrical conductors on the first surface of the light guide element may be galvanically connected to at least some of the contact terminals of the connector assembly.

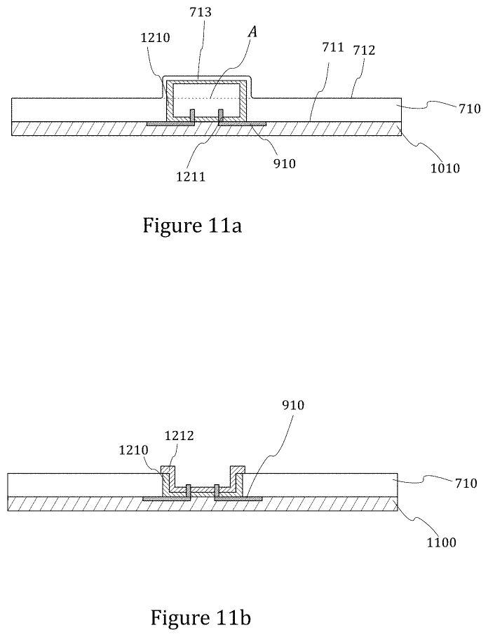

The placeholder element may be in the form of a temporary plug that is mechanically or otherwise removed. In some embodiments, the placeholder element is partially or completely removed after moulding. FIGS. 11a and 11b show a simplified example of forming a connector assembly by using a placeholder component. FIG. 11a shows a cross-sectional view of an embodiment where a placeholder element 1210 has been moulded into a light guide element 710 using a method according to the present disclosure. For example, the placeholder element may have been mounted on a carrier (along with other components) and then immersed in a hardenable substance in a mould. The light guide element 710 may then have been formed by hardening the hardenable substance. After that, conductors 910 may have been formed on the first surface 711 of the light guide element 710. At least some of the conductors 910 may be connected to contact terminals 1211 of the placeholder element 1210. As shown in FIG. 11a, the placeholder element 1210 may be a hollow, sealed structure that partially extends from the second surface 712 of the light guide element 710. However, the mould may have been formed to accommodate the placeholder element 1220 such that the portion of the placeholder element 1210 extending from the second surface 712 is covered with a thin layer 713 of the material of the light guide element 710. The extending portion of the placeholder element 1210 may be removed together with the thin layer 713 (e.g. along line A in FIG. 11a), thereby making the hollow inside of the placeholder element accessible from the side of the second surface 712. The remaining portion thus forms a base for a connector assembly. The connector assembly may then be formed on this base. The connector assembly may be configured to act as a connector receptacle (e.g. a socket for a plug) for an external connector, for example. In the context of the present disclosure, the term “external connector” refers to a physical connector device (such as a plug) that is adapted to be connected to the connector interface. The connector assembly may comprise electrical terminals configured to supply electric power to the light emitting unit, for example. In some embodiments, the external connector may also be used to provide electrical connections for controlling characteristics and/or intensity of the emitted light. In FIG. 11b, a connector assembly in the form of a socket is formed by the base part (i.e. the remaining part of the placeholder element 1210) and an additional connector-interfacing part 1211 that is attached to base part. The base and the connector-interfacing part may be threaded and/or may comprise interlocking locking device parts so that the connector-interfacing part is fixed on top of the base part on the second side of the light guide element, thereby forming a mechanically robust connection. The connector assembly may further comprise a sealing device (such as a sealing ring) between the base and the additional connector part. In addition, the connector assembly may comprise another sealing device (e.g. a sealing ring) for forming a seal between the connector assembly and a connector to be connected to the connector assembly.

While the above sections mainly discuss a partial removal of the placeholder element, the placeholder element may be completely removed in some embodiments after the moulding. Thus, the placeholder element may act as a simple plug used to form a suitable cavity to the light guide element.

The circuit element can also be something else than a connector. For example, one or more circuit elements on top of the carrier can be used for forming structural features in the first surface of the light guide element. For example, the shaped cavity formed by the removal of the placeholder element may be a small, elongated channel and the circuit element formed in the channel may be is an electrical conductor (in the form of a conducting substance that fills the channel).

Ninth, aspects of forming prefabrication elements for manufacturing a light emitting unit are discussed in more detail. In one embodiment, a first prefabrication element comprises a carrier with adhesive on its first side, and a plurality of surface-mount LED components attached to the first side, the components being attached to the first side by their bottom side so that contact terminals of the LED components engage with the adhesive on the first side. The first prefabrication element may be manufactured with a first partial manufacturing method, for example. In the context of the present application, the term “partial manufacturing method” refers to a method that performs some steps of a manufacturing method according to the present disclosure as described above. The first partial manufacturing method may comprise providing a carrier with an adhesive on its first side, placing surface-mount LED components on the first side of the carrier, the LED components being placed their bottom side facing the first side of the carrier so that contact terminals of the LED components engage with the adhesive on the first side, for example.

The first prefabrication element may be utilized in a second partial manufacturing method, for example. The second partial method comprises providing the first prefabrication element, immersing the LED components of the first prefabrication element in a viscous hardenable substance in a mould, and hardening the hardenable substance to form a light guide element. The mould defines structural features for a light guide element, and bodies of the LED components are mostly or completely embedded within the hardenable substance. The light guide element forms a frame for the light emitting unit, and the light guide element has a first surface in contact with the first side of the carrier. The second partial manufacturing method may be used to produce a second prefabrication element.

As a result, the second prefabrication element comprises a light guide element with a planar first side and an opposing second side, a plurality of surface-mount LED components embedded within the light guide element such that bodies of the LED components are mostly or completely embedded within the light guide element while contact terminals of the LED components reach to or extend from the first surface of the light guide element first side of the light guide element, and a removable cover sheet covering the first surface. The second prefabrication element may be utilized in a third partial manufacturing method, for example. The third partial manufacturing method comprises the second prefabrication element, removing the cover sheet, thereby exposing the contact terminals of the LED components on the first surface of the light guide, forming electrical circuitry on the first surface of the light guide element, and forming a dielectric layer on top of the first surface of the light guide element, thereby covering the electrical circuitry and LED components. A light emitting unit according to the present disclosure can be manufactured with the third partial manufacturing method.

Tenth, aspects of a light emitting unit according to the present disclosure are discussed in more detail. The various embodiments of a method according to the present disclosure as discussed above may be used for producing a light emitting unit with a mechanical structure that is well suited for horticultural applications. Although FIGS. 2 to 10 and the above sections of description mostly discuss methods light emitting units in reference to embodiments with a simple square shape, the light emitting unit can of course have other shapes.

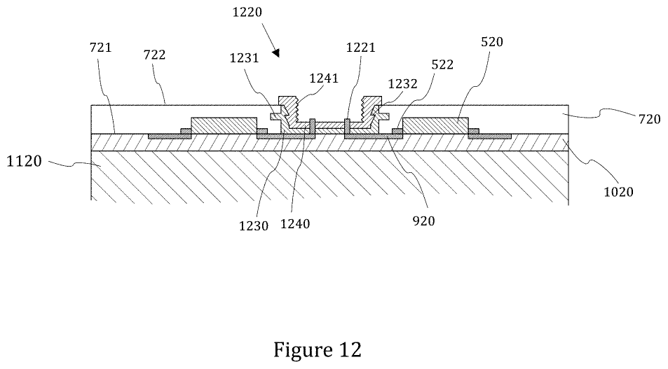

FIG. 12 shows a cross-sectional view of one embodiment of a light emitting unit according to the present disclosure. The light emitting unit may be similar to the light emitting unit of FIG. 2, for example. In FIG. 12, two LED components 520 and a connector assembly 1220 are shown. The connector assembly 1220 comprises a base part 1230 and a connector-engaging element 1240 in FIG. 12. The components 520 and a base part 1230 of the connector assembly 1220 are embedded within a light guide element 720. Electrical conductors 920 have been formed on the first surface 721 of the light guide element 720. The electrical conductors 920 form electrical connections between contact terminals 522 and 1221 of the components 520 and the connector assembly 1220, for example. The first surface 721 of the light guide element 720 has then been covered with an dielectric layer 1020, and a heat sink 1120 has been attached to outer surface of the dielectric layer 1020.

The connector assembly 1220 in FIG. 12 may have been formed in the same manner as discussed in relation to the embodiment of FIGS. 11a and 11b, for example. In FIG. 12, the connector assembly comprises a base part 1230 has extensions 1231 extending from the body of the base part 1230 to the light guide element 720. In this manner, larger contact surface between the base part 1230 and the light guide element 720 can be formed, thereby providing better mechanical support for the connector assembly 1220. In FIG. 12, the connector assembly 1220 further comprises a connector-interfacing part 1240. The contact terminals 1221 of the connector assembly 1220 extend from the first surface 721 of the light guide element 720 to the second surface 722 through the base part 1230 and the connector-interfacing part 1240. In this context, the term “connector-interfacing part” refers to a part that is configured to interface and engage with an external connector, e.g. in the form of a socket-plug pair. In other words, the connector-interfacing part 1240 is configured to function as a receptacle for an external connector and to form electrical connections between terminals of the connector assembly 1220 and contact terminals of the external connector.

In some embodiments, the base part 1230 and the connector-interfacing part 1240 may be provided with corresponding threads so as to facilitate a mechanically robust fastening between the parts. In FIG. 12, the base parts 1230 and the connector-interfacing part 1240 comprise interlocking locking parts 1232 that snap into a locked state when part 1240 is pushed into the base part 1230. The connector-interfacing part 1240 may also comprise threads for engaging with the external connector. In FIG. 12, the connector-interfacing part 1240 comprises threads 1241. In some embodiments, the connector assembly may not comprise a separate connector-interfacing part 1240 as shown in FIG. 12. Instead, the base part 1230 may directly act as a receptacle for a connector without a separate connector-interfacing part. While the above discussion mostly refers to the connector-assembly as a receptacle (e.g. in the form of a socket), the connector assembly may alternatively form a connector (e.g. a plug) to be connected a receptacle.

As FIG. 12 shows, the components 520 and the conductors 920 are sealed off from exposure to the ambient environment. The component 520 and the conductors 920 are covered by the light guide element 720 from one side and by the dielectric layer 1020 from the opposing side. Further, the connector assembly 1220 is configured to form a sealed contact with an external connector so that when the external connector has been connected to the connector assembly, the electrically sensitive parts (e.g. the components and the electrical conductors) are all within a protective casing. Because the light guide element 720, the dielectric layer 1020, and the component assembly 1220 (together with an external connector) form the protective casing, a high ingress protection can be achieved for the light emitting unit.

Eleventh, aspects of a light emitted by a light emitting unit according to the present disclosure in horticultural applications are discussed in more detail. Horticultural applications may also set some desired characteristics for the spectrum of the emitted light. For example, two important absorption peaks of photosynthetic photoreceptors are located in the red and blue regions from 625 to 675 nm and from 425 to 475 nm, respectively. Additionally, there are also other localized peaks at near-UV (300-400 nm) and in the far-red region (700-800 nm). In addition, photomorphogenetic photoreceptors of plants have sensitivity peaks in the red at 660 nm and in the far-red at 730 nm. Green light (500-600 nm) is slightly less efficient for photosynthesis of plants, as green plants reflect part of these wavelengths. A light emitting unit according to the present disclosure may be configured to produce a desired spectrum. For example, for horticultural applications, the light emitting unit may be provided with LEDs emitting light at least in the red (600-700 nm) and blue (400-500 nm) regions, for example. In some embodiments, light emitted in the red region may extend to adjacent regions (e.g. down to wavelength of 550 nm). In other words, the red region may be from 550 nm to 700 nm, for example. In addition, the light emitting unit may comprise LEDs emitting light at one or more of the other above-mentioned wavelength regions.

Further, some or all of the LEDs may be provided with a down-conversion material that converts (a part or all of) the primary emission of the LEDs into a secondary emission peaking at a second, higher wavelength. The down-conversion materials may be phosphors, for example. Alternatively, or in addition, the light guide element may be provided with down-conversion material or materials. For example, down-conversion materials (e.g. in the form of a powder) may be mixed to the hardenable substance from which the light guide element may then be formed. The use of a down-conversion material or materials may be restricted certain portions of the light guide element. For example, the light guide element may be formed in stages so that it has a layer containing down-conversion material.

A light emitting unit according to the present disclosure may comprise different kind of LEDs. For example, some of the LED components may be configured to emit only primary emission of the LED while others may be configured to use down-conversion to produce a secondary emission. Alternatively, or in addition, the LED components may have been configured to have different primary emissions, and at the primary emissions (or some portion of them) may down-converted to different secondary emissions by using one or more different down-conversion materials. By using a plurality of down-conversion materials, tailored spectral features (such as a broad spectral peak having its peak wavelength in the range of 550 nm to 700 nm). While the present disclosure discusses light spectrum mainly in view of horticultural applications, the use of a light emitting unit according to the present disclosure is not limited only to such applications. The light emitting unit may be used in generic applications, e.g. for producing white light.

It is obvious to a person skilled in the art that the method, the light emitting unit, and the prefabrication elements can be implemented in various ways. The invention and its embodiments are not limited to the examples described above but may vary within the scope of the claims.

1-17. (canceled)

18. A manufacturing method for manufacturing a light emitting unit, the method comprising
providing a carrier with an adhesive on its first side,
placing surface-mount LED components on the first side of the carrier, the LED components being placed their bottom side facing the first side of the carrier so that contact terminals of the LED components engage with the adhesive on the first side,
immersing the placed LED components in a viscous hardenable substance in a mould, wherein the mould defines structural features for a light guide element,
hardening the hardenable substance to form the light guide element so that bodies of the LED components are mostly or completely embedded within the light guide element, the light guide element forms a frame for the light emitting unit, and the light guide element has a first surface in contact with the first side of the carrier,
removing the carrier, thereby exposing the contact terminals of the LED components on the first surface of the light guide,
forming electrical circuitry on the first surface of the light guide element, and
forming a dielectric layer on top of the first surface of the light guide element, thereby covering the electrical circuitry and LED components.

19. The manufacturing method according to claim 18, the method further comprising
placing a placeholder element on the first side of the carrier, and,
after hardening the hardenable substance,
removing the placeholder element to form a shaped cavity in the light guide, and
placing a circuit element in the cavity.

20. The manufacturing method according to claim 19, wherein the circuit element is a connector assembly.

21. The manufacturing method according claim 18, wherein the method further comprises
attaching a heatsink to the first surface on top of the dielectric layer.

22. A prefabrication element for manufacturing a light emitting unit, wherein the prefabrication element comprises
a carrier with adhesive on its first side, and
a plurality of surface-mount LED components attached to the first side, the components being attached to the first side by their bottom side so that contact terminals of the LED components engage with the adhesive on the first side.

23. A prefabrication element for manufacturing a light emitting unit, wherein the prefabrication element comprises
a light guide element with a planar first side and an opposing second side,
a plurality of surface-mount LED components embedded within the light guide element such that bodies of the LED components are mostly or completely embedded within the light guide element while contact terminals of the LED components reach to or extend from the first surface of the light guide element first side of the light guide element, and
a removable cover sheet covering the first surface.

24. A light emitting unit comprising
a light guide element with a substantially planar first surface,
a plurality of surface-mount LED components embedded within the light guide element such that bodies of the LED components are mostly or completely embedded within the light guide element while contact terminals of the LED components reach to or extend from the first surface of the light guide element,
electrical conductors formed on the first surface of the light guide element, the electrical conductors being galvanically connected to at least some of the contact terminals of the LED components, and
a dielectric layer on top of the first surface of the light guide element, covering the electrical circuitry and LED components.

25. The light emitting unit according to claim 24, wherein the light emitting unit further comprises a heatsink attached to the dielectric layer.

26. The light emitting unit according to claim 24, wherein the light emitting unit further comprises
a connector assembly embedded within the light guide element such that a base part of the connector assembly is mostly or completely embedded within the light guide element while contact terminals of the connector assembly reach to or extend from the first surface of the light guide element, the electrical conductors being galvanically connected to at least some of the contact terminals of the connector assembly.

27. The light emitting unit according to claim 24, wherein the light emitting unit comprises at least 10 LED components.

28. The light emitting unit according to claim 24, wherein the light guide element is provided with down-conversion material that converts at least some part of the incident light emission to lower energy light emission.

29. The light emitting unit according to claim 24, wherein is configured to emit light at wavelength regions of 400 to 500 nm and 550 to 700 nm.

30. The light emitting unit according to claim 24, wherein the width of the light guide element is at least 3 cm and the length of the light guide element is at least 10 cm.

31. The light emitting unit according to claim 24, wherein power rating of a light emitting unit is 10 W or more.

32. The light emitting unit according to claim 26, wherein the light emitting unit further comprises a heatsink attached to the dielectric layer.

33. The light emitting unit according to claim 26, wherein the light guide element is provided with down-conversion material that converts at least some part of the incident light emission to lower energy light emission.

34. The light emitting unit according to claim 26, wherein is configured to emit light at wavelength regions of 400 to 500 nm and 550 to 700 nm.

35. The light emitting unit according to claim 32, wherein the light guide element is provided with down-conversion material that converts at least some part of the incident light emission to lower energy light emission.

36. The light emitting unit according to claim 32, wherein is configured to emit light at wavelength regions of 400 to 500 nm and 550 to 700 nm.

37. The light emitting unit according to claim 32, wherein power rating of a light emitting unit is 10 W or more.
